(19) United States
(12) Patent Application Publication
(10) Pub. No.: US 2021/0302686 A1
(43) Pub. Date: Sep. 30, 2021

(54) ANISOTROPIC ADHESIVE, LENS MODULE, AND ELECTRONIC DEVICE

(71) Applicant: TRIPLE WIN TECHNOLOGY(SHENZHEN) CO.LTD., Shenzhen (CN)

(72) Inventor: HONG-LIANG LI, Shenzhen (CN)

(21) Appl. No.: 16/872,687

(22) Filed: May 12, 2020

(30) Foreign Application Priority Data
Mar. 27, 2020 (CN) 202020423938.5

(51) Int. Cl. G02B 7/02; H05K 1/18; H01B 5/14; H05K 1/02

(52) U.S. Cl. CPC G02B 7/025; H05K 1/189; H05K 2201/10151; H05K 1/0281; H05K 2201/10121; H01B 5/14

(57) ABSTRACT

An anisotropic conductive adhesive includes a conductive layer including a first surface and a second surface opposite the first surface. The conductive layer defines at least one air guide hole penetrating the first surface and the second surface.

### FIELD

The subject matter herein generally relates to lens modules, and more particularly to an anisotropic adhesive of a lens module.

### BACKGROUND

Generally, a lens module includes an anisotropic conductive adhesive used for electrically conducting and bonding adjacent components. However, the anisotropic conductive adhesive and the components to which it is bonded form a closed space. When gas in the closed space is heated, the gas expands and a force of the gas expansion is applied directly on the anisotropic conductive adhesive, which causes the anisotropic conductive adhesive to detach from the bonded components, thereby reducing performance and reliability of the lens module.

### BRIEF DESCRIPTION OF THE DRAWINGS

Implementations of the present disclosure will now be described, by way of embodiments, with reference to the attached figures.

FIG. 1 is a schematic view of an embodiment of an anisotropic conductive adhesive.

FIG. 2A is a schematic view of an embodiment of the anisotropic conductive adhesive defining at least one air guide hole.

FIG. 2B is a schematic view of another embodiment of the anisotropic conductive adhesive defining at least one air guide hole.

FIG. 2C is a schematic view of another embodiment of the anisotropic conductive adhesive defining at least one air guide hole.

FIG. 2D is a schematic view of another embodiment of the anisotropic conductive adhesive defining at least one air guide hole.

FIG. 2E is a schematic view of another embodiment of the anisotropic conductive adhesive defining at least one air guide hole.

FIG. 3 is an assembled, isometric view of an embodiment of a lens module.

FIG. 4 is an exploded, isometric view of the lens module in FIG. 3.

FIG. 5 is similar to FIG. 4, but showing the lens module from another angle.

FIG. 6A is a schematic diagram showing the lens module using the anisotropic conductive adhesive shown in FIG. 2A.

FIG. 6B is a schematic diagram showing the lens module using the anisotropic conductive adhesive shown in FIG. 2B.

FIG. 6C is a schematic diagram showing the lens module using the anisotropic conductive adhesive shown in FIG. 2C.

FIG. 6D is a schematic diagram showing the lens module using the anisotropic conductive adhesive shown in FIG. 2D or 2E.

FIG. 7A is a cross-sectional view of a lens module in the related art.

FIG. 7B is a cross-sectional view of the lens module in the present disclosure.

FIG. 8 is an isometric view of an electronic device including the lens module of the present disclosure.

### DETAILED DESCRIPTION

It will be appreciated that for simplicity and clarity of illustration, where appropriate, reference numerals have been repeated among the different figures to indicate corresponding or analogous elements. Additionally, numerous specific details are set forth in order to provide a thorough understanding of the embodiments described herein. However, it will be understood by those of ordinary skill in the art that the embodiments described herein can be practiced without these specific details. In other instances, methods, procedures and components have not been described in detail so as not to obscure the related relevant feature being described. The drawings are not necessarily to scale and the proportions of certain parts may be exaggerated to better illustrate details and features. The description is not to be considered as limiting the scope of the embodiments described herein.

Several definitions that apply throughout this disclosure will now be presented.

The term “substantially” is defined to be essentially conforming to the particular dimension, shape, or other word that “substantially” modifies, such that the component need not be exact. For example, “substantially cylindrical” means that the object resembles a cylinder, but can have one or more deviations from a true cylinder. The term “comprising” means “including, but not necessarily limited to”; it specifically indicates open-ended inclusion or membership in a so-described combination, group, series and the like.

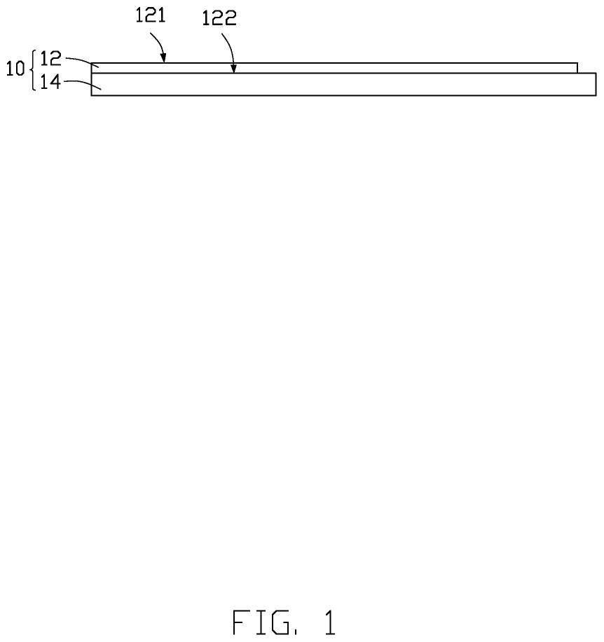

FIG. 1 shows an embodiment of an anisotropic conductive adhesive 10. The anisotropic conductive adhesive 10 includes a conductive layer 12 and a substrate 14. The substrate 14 is detachably disposed on one surface or opposite surfaces of the conductive layer 12.

The substrate 14 is a non-adhesive insulating material used for protecting the conductive layer 12.

The conductive layer 12 includes a first surface 121 and a second surface 122. The first surface 121 is opposite the second surface 122. In one embodiment, the first surface 121 and the second surface 122 are parallel. The first surface 121 and the second surface 122 are both adhesive. The conductive layer 12 is used for bonding components, wherein one component is located on the first surface 121, and another component is located on the second surface 122.

The conductive layer 12 has electrical conductivity for electrically conducting the components located on both sides of the conductive layer 12.

The conductive layer 12 defines at least one air guide hole 123 that penetrates the first surface 121 and the second surface 122.

A shape of the air guide hole 123 may be, but is not limited to, rectangular, circular, elliptical, triangular, trapezoidal, or a combination thereof.

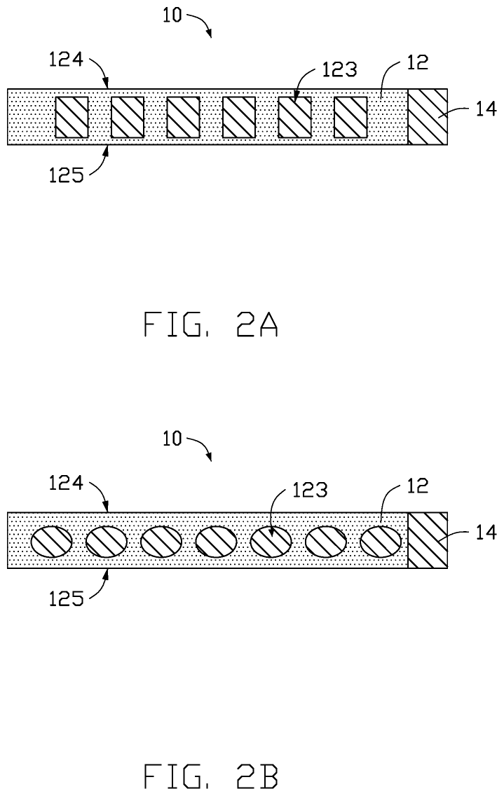

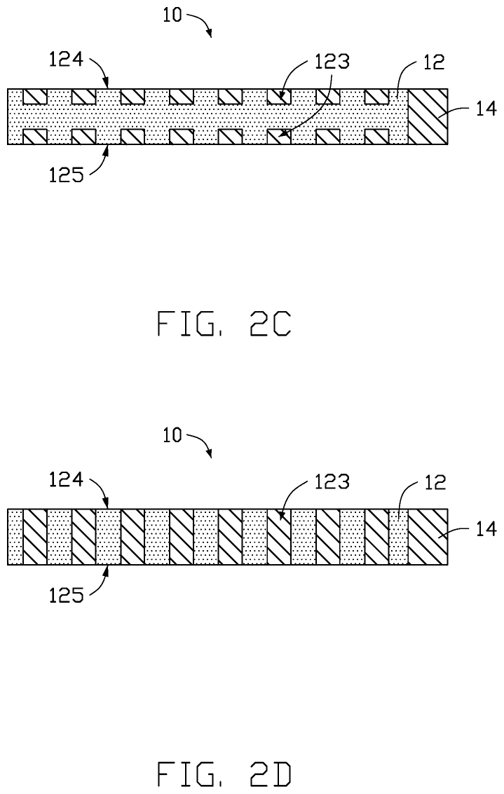

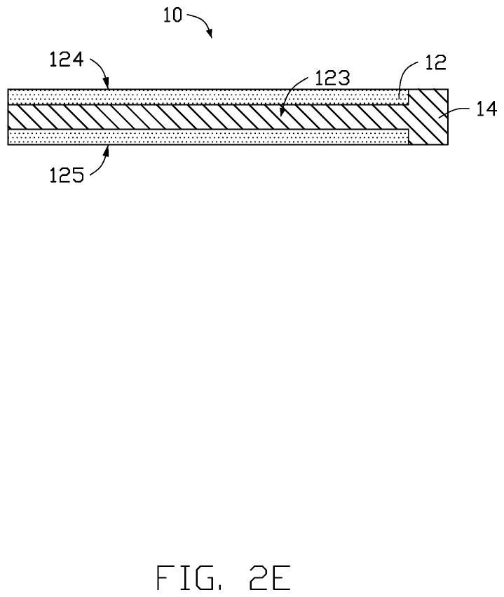

Referring to FIG. 2A, the conductive layer 12 includes a first side 124 and a second side 125. The first side 124 and the second side 125 are opposite side edges of the conductive layer 12 and parallel. The conductive layer 12 defines a plurality of rectangular air guide holes 123 spaced at intervals along a lengthwise direction of the conductive layer 12. The air guide holes 123 are equally spaced from the first side 124 and the second side 125.

Referring to FIG. 2B, in another embodiment, the conductive layer 12 defines a plurality of elliptical air guide holes 123 arranged at intervals along the lengthwise direction of the conductive layer 12. The air guide holes 123 are equally spaced from the first side 124 and the second side 125.

Referring to FIG. 2C, in another embodiment, the conductive layer 12 defines a plurality of rectangular air guide holes 123 arranged at intervals along the lengthwise direction of the conductive layer 12. Each of the air guide holes 123 penetrates the first side 124 or the second side 125.

Referring to FIG. 2D, in another embodiment, the conductive layer 12 defines a plurality of rectangular air guide holes 123 arranged at intervals along the lengthwise direction of the conductive layer 12. Each of the air guide holes 123 penetrates the first side 124 and the second side 125, thereby dividing the conductive layer 12 into a plurality of sections each disposed on the substrate 14.

Referring to FIG. 2E, in another embodiment, the conductive layer 12 defines one air guide hole 123 extending along a middle of the conductive layer 12 and the lengthwise direction of the conductive layer 12, thereby dividing the conductive layer 12 into two sections. The air guide hole 123 extends parallel to the first side 124 and the second side 125.

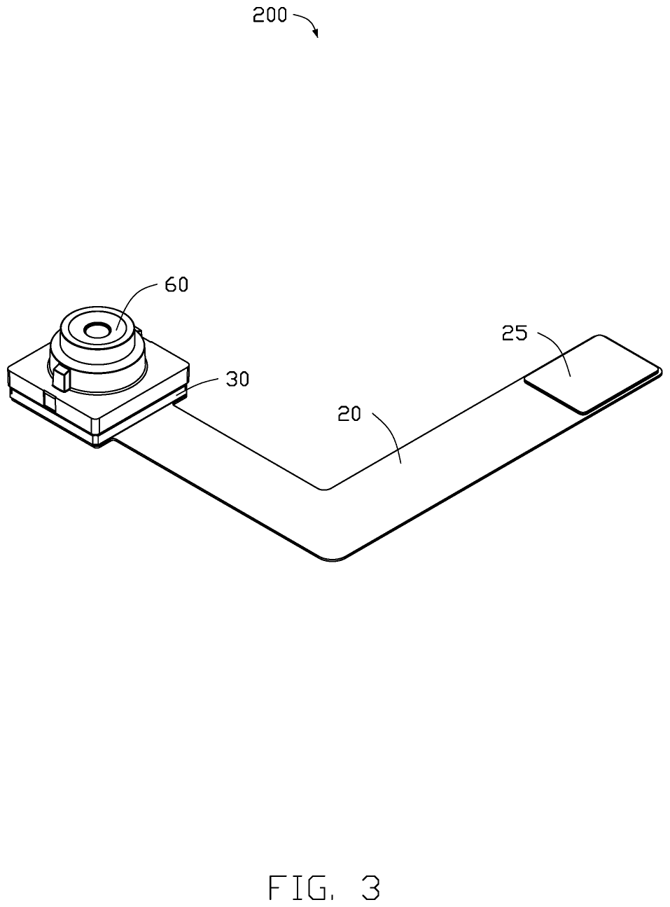

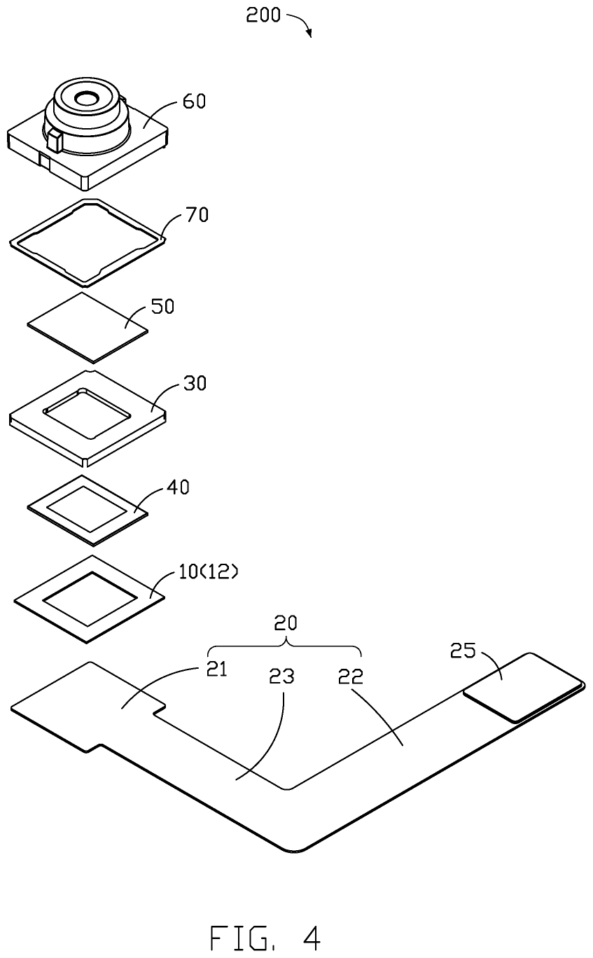

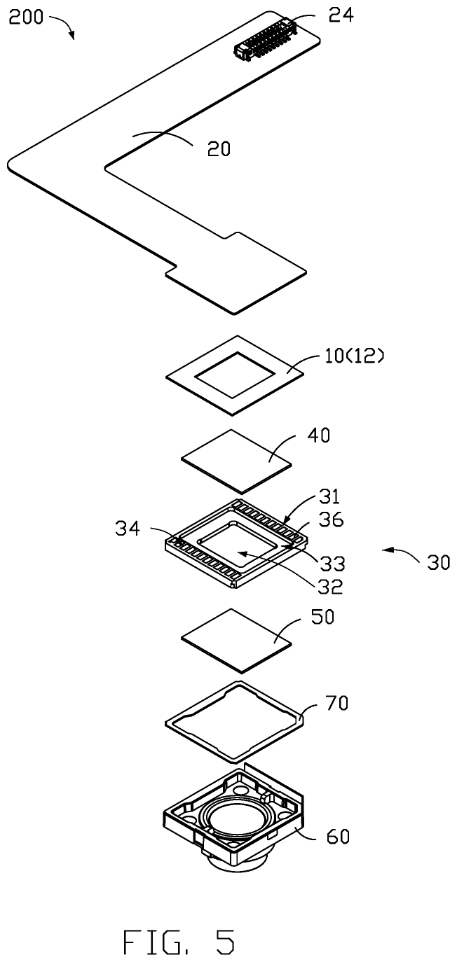

FIGS. 3-5 show an embodiment of a lens module 200. The lens module 200 includes a circuit board 20, the anisotropic conductive adhesive 10, a photosensitive chip 40, a carrier plate 30, a filter 50, and a lens assembly 60.

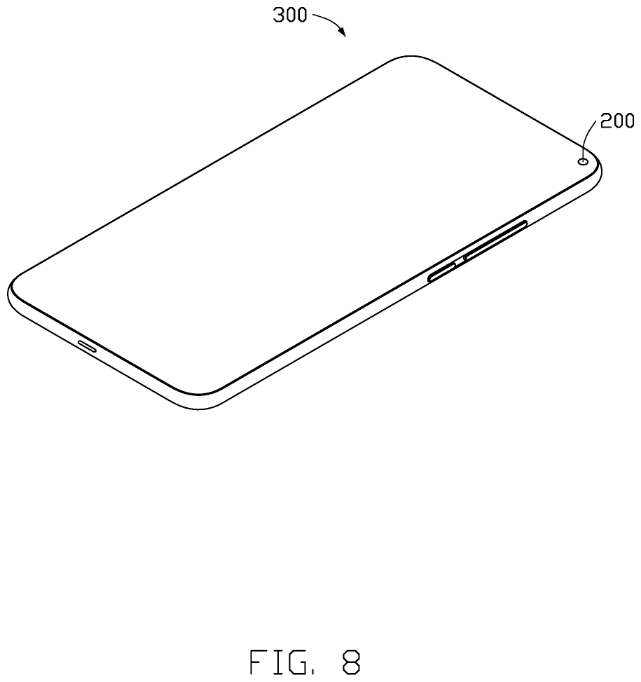

The circuit board 20 may be a flexible board, a rigid board, or a rigid-flex board. In one embodiment, the circuit board 20 is a rigid-flex board, which includes a first hard portion 21, a second hard portion 22, and a flexible portion 23 located between the first hard portion 21 and the second hard portion 22. An electrical connection portion 24 is mounted on a surface of the second hard portion 22. When the lens module 200 is applied to an electronic device 300 (shown in FIG. 8), the electrical connection portion 24 is used for transmitting signals between the lens module 200 and other components of the electronic device 300. The electrical connection portion 24 may be a connector or a gold finger. A reinforcement plate 25 is mounted on a surface of the second hard portion 22 opposite the surface with the electrical connection portion 24. A material of the reinforcement plate 25 is metal (such as stainless steel).

The carrier plate 30 is mounted on a surface of the first hard portion 21, and the carrier plate 30 and the electrical connection portion 24 are located on different surfaces of the circuit board 20.

The carrier plate 30 is substantially a hollow rectangular structure. The carrier plate 30 includes a mounting surface 31 facing the circuit board 20 and defines a through hole 32. A portion of the mounting surface 31 adjacent to the through hole 32 is recessed inward to define a recess 33 for receiving the photosensitive chip 40. A size of the photosensitive chip 40 is larger than a size of the through hole 32 and smaller than a size of the recess 33. The photosensitive chip 40 completely covers the through hole 32.

A portion of the mounting surface 31 adjacent to the recess 33 is recessed inward to define a plurality of receiving grooves 34 for receiving a plurality of solder pads 36. A surface of the solder pads 36 exposed from the receiving grooves 34 is flush with the mounting surface 31.

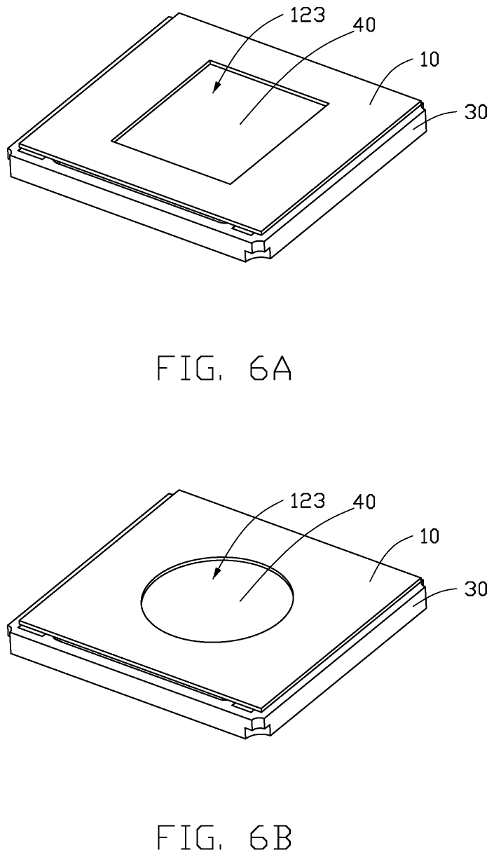

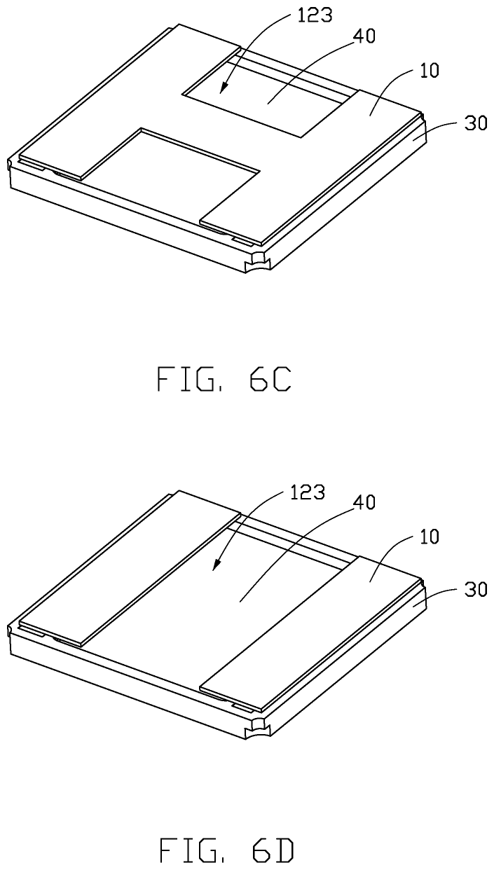

FIG. 6A, FIG. 6B, and FIG. 6C are schematic diagrams showing the lens module 200 using the anisotropic conductive adhesive 10 shown in FIG. 2A, FIG. 2B, and FIG. 2C, respectively. FIG. 6D is a schematic diagram showing the lens module 200 using the anisotropic conductive adhesive 10 shown in FIG. 2D or 2E. The anisotropic conductive adhesive 10 is located between the circuit board 20 and the carrier plate 30. The anisotropic conductive adhesive 10 is used for bonding the circuit board 20 and the carrier plate 30 and electrically conducting the circuit board 20 and the solder pads 36. Positions of the air guide holes 123 do not overlap with a position of the solder pads 36, so as to facilitate the solder pads 36 to electrically connect to the circuit board 20 through the anisotropic conductive adhesive 10.

It can be understood that when the anisotropic conductive adhesive 10 is applied to the lens module 200, the substrate 14 is removed, and the conductive layer 12 is cut according to actual needs, so that a size of the conductive layer 12 matches a size of the carrier plate 30 and the circuit board 20, and at least one air guide hole 123 communicates with the recess 33.

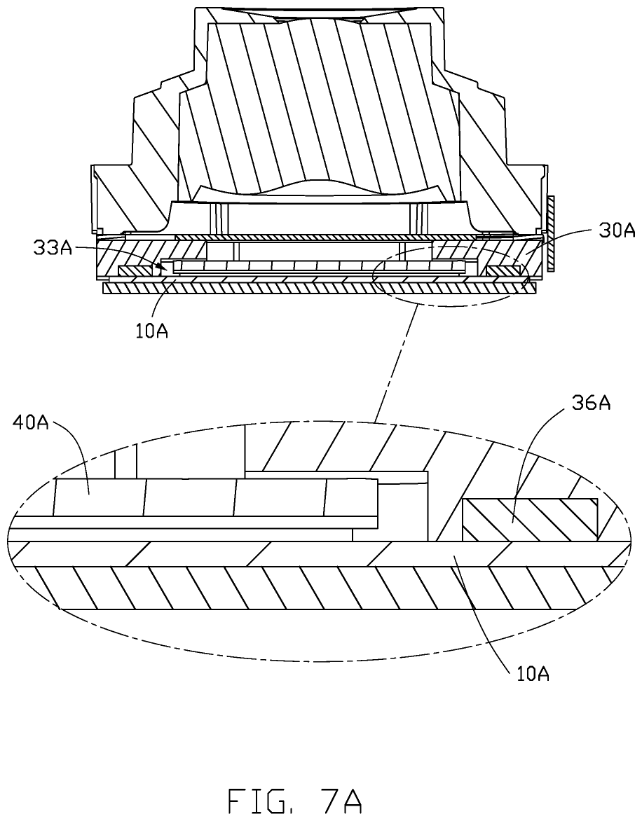

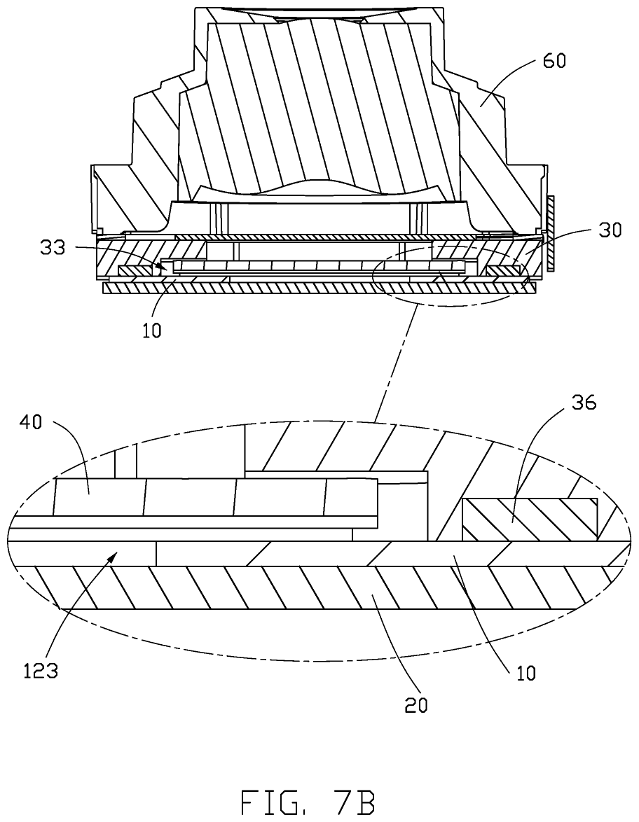

Referring to FIG. 7A, in the related art, an anisotropic conductive adhesive 10A is not provided with air guide holes. When the anisotropic conductive adhesive 10A is attached to a mounting surface of a carrier plate 30A, the anisotropic conductive adhesive 10A, the carrier plate 30A, and a photosensitive chip 40A form a closed space. When gas in a groove 33A is heated, such as when the ambient temperature rises, the heat generated by the lens module cannot be dissipated in time, and the gas in the groove 33A expands due to the heat. The gas expansion acts on the anisotropic conductive adhesive 10A, which reduces a connection between the anisotropic conductive adhesive 10A and solder pads 36A.

Referring to FIG. 7B, in the present disclosure, the anisotropic conductive adhesive 10 is provided with the air guide holes 123. When the anisotropic conductive adhesive 10 bonds the circuit board 20 and the carrier plate 30, the anisotropic conductive adhesive 10, the carrier plate 30, and the photosensitive chip 40 form an open space. When gas in the recess 33 expands, a force of the gas expansion is mainly applied on the carrier plate 30 and the circuit board 20, and not directly applied on the anisotropic conductive adhesive 10. Therefore, expansion of the gas in the recess 33 does not cause a connection failure between the conductive layer 12 and the solder pads 36.

The filter 50 is located on a surface of the carrier plate 30 facing away from the circuit board 20, and the filter 50 is spaced from the photosensitive chip 40.

The lens assembly 60 is located on the surface of the carrier plate 30 facing away from the circuit board 20. In one embodiment, the lens assembly 60 is fixed on the carrier plate 30 by a fixing adhesive 70.

Understandably, the lens module 200 can be applied to various electronic devices 300, such as a mobile phone, a wearable device, a computer device, a vehicle, a drone, a robot, or a monitoring device. Referring to FIG. 8, the lens module 200 is applied to a mobile phone.

The anisotropic conductive adhesive 10 defines the air guide holes 123, so that when the gas in the recess 33 expands, the force of the gas expansion is applied on the carrier plate 30 and the circuit board 20 through the air guide holes 123, thereby preventing the force of the gas expansion from directly applying on the anisotropic conductive adhesive 10. Thus, the connection between the anisotropic conductive adhesive 10 and the solder pads 36 is maintained, thereby improving reliability of performance of the lens module 200.

The embodiments shown and described above are only examples. Even though numerous characteristics and advantages of the present technology have been set forth in the foregoing description, together with details of the structure and function of the present disclosure, the disclosure is illustrative only, and changes may be made in the detail, including in matters of shape, size and arrangement of the parts within the principles of the present disclosure up to, and including, the full extent established by the broad general meaning of the terms used in the claims.

What is claimed is:

1. An anisotropic conductive adhesive comprising:
a conductive layer comprising a first surface and a second surface opposite the first surface; wherein:
the conductive layer defines at least one air guide hole penetrating the first surface and the second surface.

2. The anisotropic conductive adhesive of claim 1, wherein:
a shape of the air guide hole comprises, but is not limited to, rectangular, circular, elliptical, triangular, trapezoidal, or a combination thereof.

3. The anisotropic conductive adhesive of claim 2, wherein:
the conductive layer comprises a first side and a second side;
the first side is opposite the second side;
the conductive layer defines a plurality of air guide holes spaced at intervals along a lengthwise direction of the conductive layer; and
the air guide holes are equally spaced from the first side and the second side.

4. The anisotropic conductive adhesive of claim 2, wherein:
the conductive layer comprises a first side and a second side;
the first side is opposite the second side;
the conductive layer defines a plurality of air guide holes spaced at intervals along a lengthwise direction of the conductive layer; and
the air guide holes penetrate the first side and/or the second side.

5. The anisotropic conductive adhesive of claim 2, wherein:
the conductive layer comprises a first side and a second side;
the first side is opposite the second side;
the conductive layer defines one air guide hole extending along a middle of the conductive layer and a lengthwise direction of the conductive layer, thereby dividing the conductive layer into two sections; and
the air guide hole extends parallel to the first side and the second side.

6. The anisotropic conductive adhesive of claim 1, wherein:
the first surface and the second surface are adhesive.

7. The anisotropic conductive adhesive of claim 1, further comprising a substrate detachably disposed on one surface or opposite surfaces of the conductive layer.

8. A lens module comprising:
a circuit board;
a carrier plate comprising a mounting surface for mounting the carrier plate to the circuit board, a middle of the carrier plate defining a through hole, a portion of the mounting surface adjacent to the through hole recessed inward to define a recess, the carrier plate comprising solder pads on a portion of the mounting surface outside of the recess;
a photosensitive chip received in the recess and covering the through hole; and
an anisotropic conductive adhesive comprising a conductive layer comprising a first surface and a second surface opposite the first surface; wherein:
the conductive layer defines at least one air guide hole penetrating the first surface and the second surface;
the first surface is adhered to the mounting surface of the carrier plate;
the second surface is adhered to the circuit board; and
the recess communicates with the at least one air guide hole.

9. The lens module of claim 8, further comprising a lens assembly; wherein:
the lens assembly is mounted on a surface of the carrier plate facing away from the circuit board.

10. The lens module of claim 9, wherein:
the conductive layer comprises a first side and a second side;
the first side is opposite the second side;
the conductive layer defines a plurality of air guide holes spaced at intervals along a lengthwise direction of the conductive layer; and
the air guide holes are equally spaced from the first side and the second side.

11. The lens module of claim 9, wherein:
the conductive layer comprises a first side and a second side;
the first side is opposite the second side;
the conductive layer defines a plurality of air guide holes spaced at intervals along a lengthwise direction of the conductive layer; and
the air guide holes penetrate the first side and/or the second side.

12. The lens module of claim 9, wherein:
the conductive layer comprises a first side and a second side;
the first side is opposite the second side;
the conductive layer defines one air guide hole extending along a middle of the conductive layer and a lengthwise direction of the conductive layer, thereby dividing the conductive layer into two sections; and
the air guide hole extends parallel to the first side and the second side.

13. The lens module of claim 8, wherein:
the first surface and the second surface are adhesive.

14. An electronic device comprising a lens module, the lens module comprising:
a circuit board;
a carrier plate comprising a mounting surface for mounting the carrier plate to the circuit board, a middle of the carrier plate defining a through hole, a portion of the mounting surface adjacent to the through hole recessed inward to define a recess, the carrier plate comprising solder pads on a portion of the mounting surface outside of the recess;
a photosensitive chip received in the recess and covering the through hole;
an anisotropic conductive adhesive comprising a conductive layer comprising a first surface and a second surface opposite the first surface; and
a lens assembly; wherein:
the conductive layer defines at least one air guide hole penetrating the first surface and the second surface;
the first surface is adhered to the mounting surface of the carrier plate;
the second surface is adhered to the circuit board; and
the recess communicates with the at least one air guide hole.

15. The electronic device of claim 14, wherein:
the lens assembly is mounted on a surface of the carrier plate facing away from the circuit board.

16. The electronic device of claim 15, wherein:
the conductive layer comprises a first side and a second side;
the first side is opposite the second side;
the conductive layer defines a plurality of air guide holes spaced at intervals along a lengthwise direction of the conductive layer; and
the air guide holes are equally spaced from the first side and the second side.

17. The electronic device of claim 15, wherein:
the conductive layer comprises a first side and a second side;
the first side is opposite the second side;
the conductive layer defines a plurality of air guide holes spaced at intervals along a lengthwise direction of the conductive layer; and
the air guide holes penetrate the first side and/or the second side.

18. The electronic device of claim 15, wherein:
the conductive layer comprises a first side and a second side;
the first side is opposite the second side;
the conductive layer defines one air guide hole extending along a middle of the conductive layer and a lengthwise direction of the conductive layer, thereby dividing the conductive layer into two sections; and
the air guide hole extends parallel to the first side and the second side.

19. The electronic device of claim 14, wherein:
the first surface and the second surface are adhesive.
